(19) United States
(12) Patent Application Publication
(10) Pub. No.: US 2011/0034014 A1
(43) Pub. Date: Feb. 10, 2011

(54) COLD IMPLANT FOR OPTIMIZED SILICIDE FORMATION

(75) Inventors: Christopher R. Hatem, Salisbury, MA (US); Benjamin Colombeau, Salem, MA (US); Thirumal Thanigaivelan, North Andover, MA (US); Kyu-Ha Shim, Andover, MA (US); Jay T. Scheuer, Rowley, MA (US)

Correspondence Address: VARIAN SEMICONDUCTOR EQUIPMENT ASSC., INC., 35 DORY RD., GLOUCESTER, MA, 01930-2297, US

(73) Assignee: VARIAN SEMICONDUCTOR EQUIPMENT ASSOCIATES, INC., Gloucester, MA (US)

(21) Appl. No.: 12/850,271

(22) Filed: Aug. 4, 2010

Related U.S. Application Data
(60) Provisional application No. 61/232,147, filed on Aug. 7, 2009.

(51) Int. Cl. H01L 21/265; H01L 21/425; H01L 21/38

(52) U.S. Cl. 438/530; 438/514; 438/914; 257/E21.334

(57) ABSTRACT

A method of applying a silicide to a substrate while minimizing adverse effects, such as lateral diffusion of metal or “piping” is disclosed. The implantation of the source and drain regions of a semiconductor device are performed at cold temperatures, such as below 0° C. This cold implant reduces the structural damage caused by the impacting ions. Subsequently, a silicide layer is applied, and due to the reduced structural damage, metal diffusion and piping into the substrate is lessened. In some embodiments, an amorphization implant is performed after the implantation of dopants, but prior to the application of the silicide. By performing this pre-silicide implant at cold temperatures, similar results can be obtained.

This application claims priority of U.S. Provisional Patent Application Ser. No. 61/232,147, filed Aug. 7, 2009, the disclosure of which is incorporated herein in its entirety.

### FIELD

This invention relates to ion implantation, and, more particularly, to implantation at temperatures to optimize silicide formation.

### BACKGROUND

Ion implantation is one of several processes used to manufacture semiconductor devices. Such semiconductor devices may include complementary metal-oxide-semiconductor (CMOS) devices, N-type metal-oxide-semiconductor (NMOS) devices and P-type metal-oxide-semiconductor (PMOS) devices. In manufacturing the device, portions of a semiconductor substrate are implanted with dopants. Generally, dopants may be atoms or molecules with properties that differ from those of the original substrate. Once implanted, the dopants may alter the properties of the implanted regions such that the resulting substrate may have discrete regions with different properties. In addition to the implanted dopants, discrete regions with different properties in the substrate may form by ion implantation as the implantation induces defects.

One method of introducing dopants into a semiconductor substrate is through the use of an ion implanter. An ion implanter includes an ion source for converting a gas or a solid material into a well-defined ion beam. The ion beam typically is mass analyzed to eliminate undesired ion species, accelerated to a desired energy, and implanted into a target. The ion beam may be distributed over the target area by electrostatic or magnetic beam scanning, by target movement, or by a combination of beam scanning and target movement. The ion beam may be a spot beam or a ribbon beam having a long dimension and a short dimension.

Ion implantation may be used for source and drain implants in, for example, an NMOS device. Further steps may add silicide layers to the source or drain, such as to provide contacts to these regions. However, there are problems that may occur during this silicidation step. Accordingly, there is a need in the art for an improved implantation method at temperatures that optimize silicide formation.

### SUMMARY

A method of applying a silicide to a substrate while minimizing adverse effects, such as lateral diffusion of metal or “piping” is disclosed. The implantation of the source and drain regions of a semiconductor device are performed at cold temperatures, such as below 0° C. This cold implant reduces the structural damage caused by the impacting ions. Subsequently, a silicide layer is deposited, and due to the reduced structural damage, metal diffusion and piping into the substrate is lessened. In some embodiments, an amorphization implant is performed after the implantation of ions (such as dopants, neutrals or other species), but prior to the application of the silicide. By performing this pre-silicide implant at cold temperatures, similar results can be obtained.

### BRIEF DESCRIPTION OF THE DRAWINGS

For a better understanding of the present disclosure, reference is made to the accompanying drawings, which are incorporated herein by reference and in which:

FIG. 1 is a simplified block diagram of a beam-line ion implanter;

FIG. 2 is a cross-sectional view of a NMOS transistor;

FIGS. 3A-3B are cross-sectional views of a regular implant and an implant at reduced temperature;

FIG. 4 is a cross-sectional view of NiSi formation on a source-drain;

FIG. 5 is a cross-sectional view of a “pipe”; and

FIG. 6 is a graph comparing P concentration to depth.

### DETAILED DESCRIPTION

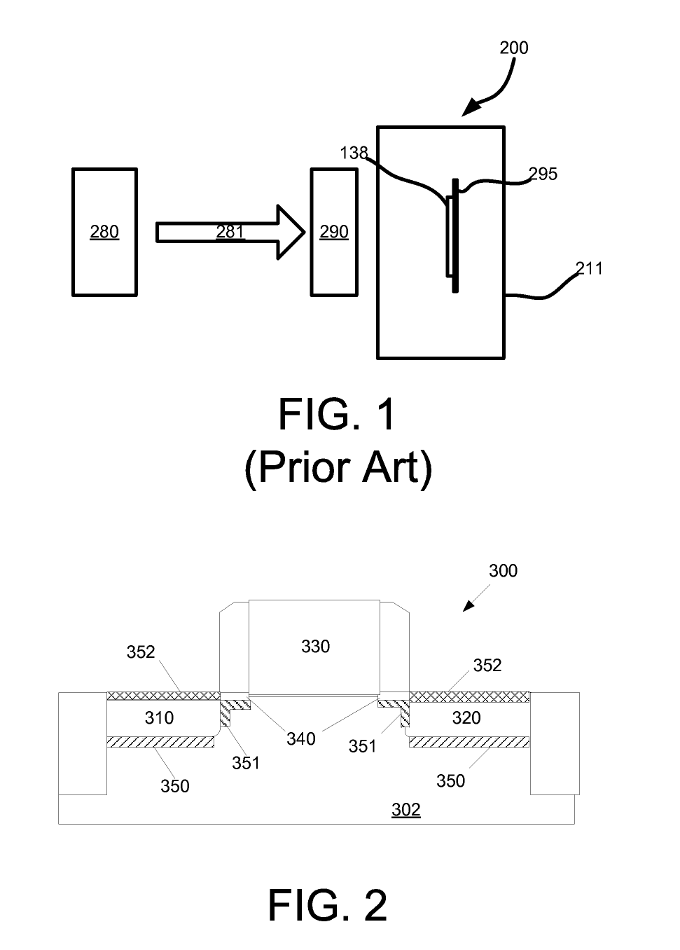

FIG. 1 is a simplified block diagram of a beam-line ion implanter. Those skilled in the art will recognize that the beamline ion implanter 200 is only one of many examples of differing beamline ion implanters. In general, the beamline ion implanter 200 includes an ion source 280 to generate ions that are extracted to form an ion beam 281, which may be, for example, a ribbon beam or a spot beam. The ion beam 281 may be mass analyzed and converted from a diverging ion beam to a ribbon ion beam with substantially parallel ion trajectories in one instance. The beamline ion implanter 200 may further include an acceleration or deceleration unit 290 in some embodiments.

An end station 211 supports one or more workpieces, such as substrate 138, in the path of the ion beam 281 such that ions of the desired species are implanted into substrate 138. In one instance, the substrate 138 may be a semiconductor wafer having a disk shape, such as, in one embodiment, a 300 mm diameter silicon wafer. However, the substrate 138 is not limited to a silicon wafer. The substrate 138 could also be, for example, a flat panel, solar, or polymer substrate. The end station 211 may include a platen 295 to support the substrate 138. The end station 211 also may include a scanner (not shown) for moving the substrate 138 perpendicular to the long dimension of the ion beam 281 cross-section, thereby distributing ions over the entire surface of substrate 138.

The ion implanter 200 may include additional components known to those skilled in the art such as automated workpiece handling equipment, Faraday sensors, or an electron flood gun. It will be understood to those skilled in the art that the entire path traversed by the ion beam is evacuated during ion implantation. The beamline ion implanter 200 may incorporate hot or cold implantation of ions in some embodiments.

One skilled in the art will recognize other systems and processes involved in semiconductor manufacturing, other systems and processes involved in plasma treatment, or other systems and processes that use accelerated ions that may perform the process described herein. Some examples of this, for example, are a plasma doping tool, an ion shower, or a plasma immersion tool. Other semiconductor processing equipment known to those skilled in the art that can accelerate species and implant species into a substrate also may be used. Thus, this process is not limited solely to beam-line ion implanters.

FIG. 2 is a cross-sectional view of a NMOS transistor 300. During an ion implantation step, the source 310 and drain 320 adjacent the gate 330 are doped with N-type dopants, such as atomic or molecular ions comprising phosphorus or other group V elements. In some embodiments, to improve semiconductor performance, a source-drain extension (SDE) 340 is implanted. These implants are used to extend the source 310 and drain 320 beneath the gate 330. Implanting dopants into the source 310 or drain 320, however, will amorphize the crystal lattice of the substrate 302. Implantation also may cause defects to the crystal lattice.

There are several types of defects. Damage caused at the boundary between the bulk substrate and the amorphized portion is known as end-of-range (EOR) defects. These EOR defects may be located at the lower penetration range of the implanted ions, as represented by 350. The location of this EOR damage is typically parallel to the substrate surface, as the implant is typically performed in a direction perpendicular to the surface of the substrate. These EOR defects 350 may cause junction leakage. In addition, the use of an SDE implant may cause EOR damage that is located beneath the gate 330, as represented by 351. In some embodiments, since the SDE implant may be performed at an angle, the EOR damage caused by the SDE implant may be perpendicular to the substrate surface, or at least may not be parallel to the substrate surface. This damage may be referred to as lateral damage. Lateral diffusion may allow silicide to pipe into the depletion region, thereby increasing junction leakage. Lateral diffusion may also lead to short channel effects (SCE). Damage is also caused at the surface of the substrate, as represented by 352. While annealing the substrate after implantation may serve to cure and repair some of the damage caused, the anneal process cannot repair all of the damage. Each of these defects may cause problems with device performance. In some embodiments, this damage creates diagonally sloped downward channels within the substrate 302.

In some embodiments, contacts made from metal-based compounds, such as metal silicides, including nickel silicide, have been used to form contacts on the source 310 and drain 320. However, previously, metal used for contacts on the source or drain would “pipe down” any damage or defect in the source or drain outside of the desired location. “Piping” occurs when metal migrates laterally into the substrate at the location of residual damage and stacking faults. Introduction of metal into the substrate due to piping adversely changes the performance and characteristics of the device.

One method to reduce the piping effect may be to perform implantation of dopants at reduced temperature on the source and drain. This implantation may be performed below approximately 0° C. or, for example, approximately −100° C. The term reduced or cold temperature is used to refer to any implant performed at a temperature of 0° C. or below, such as between 0° C. and −100° C.

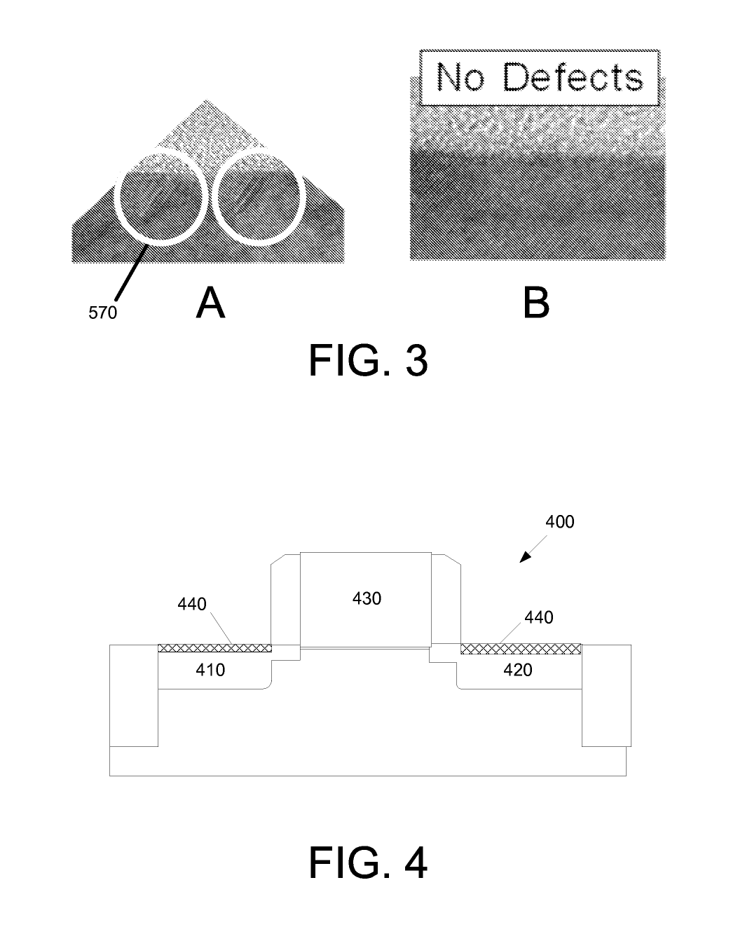

The dopants may be, for example, Group III or Group V elements, such as B, As, P in ionic atomic or molecular form. For example, boron atoms may be implanted as B ions or as carborane ions. Performing this cold implant will enhance amorphization quality and reduce surface damage, lateral damage, and end of range damage to the source and drain. FIG. 3A-3B are cross-sectional views of a regular implant and an implant at reduced temperature. In FIG. 3A, the circled regions 570 indicate surface defects or damage. These damaged regions 570 may be sloped diagonally downward as seen in FIG. 3A. Note that in FIG. 3B, such defects or damage do not exist due to the reduced temperature.

Damage may be reduced, in part, because the cold temperature constricts the crystal lattice of the substrate. Amorphization of this substrate is improved and, consequently, interface roughness between the amorphized and non-amorphized regions is improved. During an anneal, this reduced damage caused by implantation is effectively recrystallized and the subsequent NiSi during silicidation formation results in less “piping.” FIG. 4 is a cross-sectional view of a NMOS transistor 400, having a source 410 and a drain 420, each adjacent to a gate 430. Regions 440 are the desired locations where the NiSi is formed during silicidation.

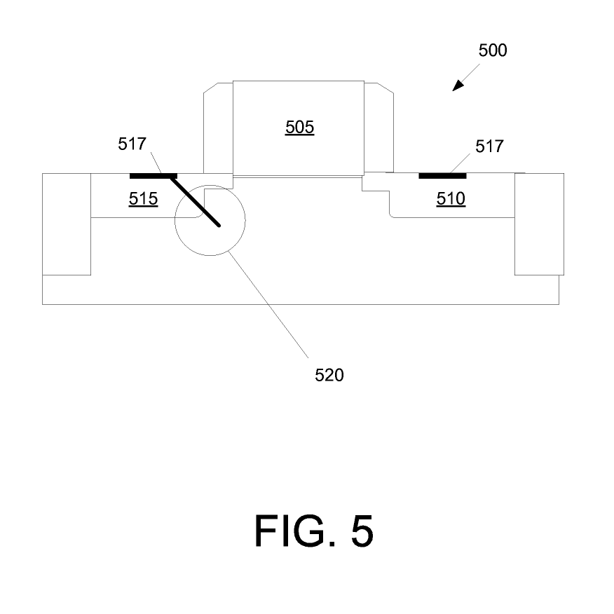

FIG. 5 is a cross-sectional view of a “pipe.” A semiconductor device 500 includes a gate 505, a source 510 region and a drain 515 region. Metal silicide is deposited on a portion of the source 510 and drain 515 regions to create contacts 517. If there is sufficient damage, the metal will laterally diffuse into the substrate. The circled region 520 is an example of a pipe.

Lateral diffusion of the metal silicide, such as NiSi, is likewise reduced by performing a cold temperature implant. This prevents the silicide from being within the depletion region of the device and, therefore, reduces junction leakage. Furthermore, by avoiding lateral growth of NiSi, the gate edge leakage current is reduced. This may reduce standby current and increase the yield of an SRAM cell. Reference flow has a random effect that can be compensated for with the addition of, for example, Pt. Cold temperature implants allow an independent control of this effect. For example, performing a cold temperature implant and the addition of Pt in the NiSi has been shown to increase yield gain. Increasing the percent Pt in the NiSi appears to further increase yield gain.

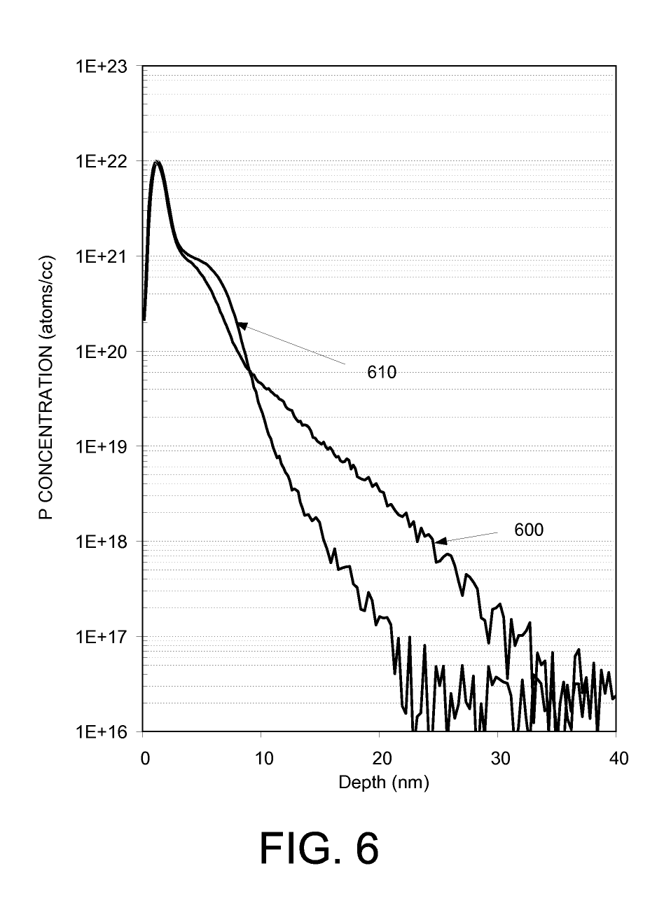

FIG. 6 is a graph comparing phosphorus (P) concentration, after activation, to depth. The implants were performed under the following conditions. The phosphorus was implanted at an implant energy of 1 Kev and a dose of 2e15. The carbon was implanted at an implant energy of 5 Kev and a dose of 5e14. Use of cold or low-temperature implants may be applied to implants of two species implanted sequentially or at least partly simultaneously, such as, for example, P and C. Line 600 shows the concentration of phosphorus as a function of depth for a phosphorus/carbon implant done under normal temperatures. Line 610 shows the same relationship when the implant is performed at cold temperature. Note that at cold temperatures, the concentration of phosphorus decreases much more quickly as a function of depth, creating a shallower implant, with a more defined depth. For example, the phosphorus concentration of the cold implant moves below 1E+19 atoms/cc at a depth of roughly 12 nm. In contrast, the phosphorus concentration of the conventional implant moves below 1E+19 atoms/cc at a depth of roughly 18 nm. Thus, if other conditions are maintained, the cold temperature ion implantation process results in shallower junction depth and more abrupt dopant concentration profile after activation.

A cold temperature implant of the source, drain, or contact may result in better amorphization, reduced contact resistance, and improved dopant activation. Not only would “piping” be reduced, but activation is increased. This is due to less EOR damage which, in turn, results in less interstitials, less transient enhanced diffusion (TED), and better activation. Thus, it is easier for dopants to get into substitutional sites.

Thus, in one embodiment, the source and drain regions are implanted with dopants, such as atomic or molecular ions comprising Group III or Group V elements, such as phosphorus or arsenic, at cold temperatures. This implant continues until the appropriate concentration of dopant has been implanted in the selected regions. Concentrations of dopants are well known to those skilled in the art. Following the implantation, a thermal anneal process may be performed in order to activate the dopants. This anneal can be either using the combination of soak anneal and/or spike anneal and/or millisecond anneal. Following the anneal process, a silicide layer is deposited on the source and drain regions. The silicide layer may be introduced using a variety of methods, such as, but not limited to sputter or chemical vapor deposition (CVD). As described above, the nickel silicide will laterally diffuse and “pipe” to a lesser extent in this process, than in conventional manufacturing processes. After the silicide is introduced, a fast anneal cycle, such as RTP, fast anneal (<1 ms) including spike, laser or FLASH anneals, may be used. These anneal cycles are well known in the art.

There may also be benefits to performing a cold temperature pre-silicide implant, after the ions (such as dopants, neutrals or other species) have been implanted. In this embodiment, the dopant implant may be performed at cold temperature, or alternatively, may be performed at more traditional operating conditions, such as room temperature. These pre-silicide implants may be ions such as silicon, though other ions are possible. A cold pre-silicide implant will amorphize a shallow region of the drain or source and destroy any surface damage. The silicide will then be deposited on the amorphized region. This amorphized region is designed to at least partly control the lateral growth of the nickel “piping.” The cold temperature will improve amorphization, interface, and roughness and provide a better silicide interface. Thus, there will be less vertical and lateral growth of the NiSi. In contrast, use of an ion, such as Xe, without cold temperatures, will cause EOR damage and form a jagged interface. The cold temperature pre-silicide implant also will reduce EOR damage or residual implant damage. There will be less or no stress or strain during a cold temperature Si implant. Current is improved and better contact resistance may be achieved. Lastly, since a cold temperature pre-silicide implant causes less damage, it is possible that ions smaller than Xe could be used for this purpose with an equivalent amorphization thickness. Light ions will cause less implant damage than Xe and are not as sensitive to adding strain or stress as occurs with Xe. For example, ions such as He, C or Si, may be used to perform the pre-silicide implant. In other embodiments, ions of any type including dopants (from Group III or Group V), metals, impurities, neutral species, and halogens, may be used.

Furthermore, use of lighter ions for a pre-silicide implant may have other advantages. Currently, Xe is used for pre-silicide implants. Due to its mass, Xe creates excessive damage to the implanted regions. It has been found that this damage may degrade the performance of PMOS structures, such as deactivating the dopants. Consequently, if a pre-silicide implant is currently performed, a masking step is required to mask the P doped regions of the CMOS device, such that only N type regions are implanted with the Xe atoms. However, if a cold temperature pre-silicide implant is performed, lighter ions can be employed. These lighter ions do not cause damage to the same extent as Xe, and therefore may be used to perform pre-silicide implants on P type regions as well. Therefore, cold temperature per-silicide implants allow the elimination of the mask step currently required to mask the PMOS structures. This results in improved silicide contacts for PMOS structures, and also saves processing times and steps.

In practice, an ion implantation is performed to introduce dopants to the source and drain regions. This ion implantation may be done at cold temperature, or may be performed at other temperatures, such as room temperature. The substrate may then be annealed, such as by furnace, laser or other means, which are well known in the art. Following introduction of the dopants, a pre-silicide implant is performed. The substrate, and particularly those regions onto which silicide will be applied, is amorphized at cold temperature. This amorphization is performed at cold temperature, and preferably involves implantation of smaller atoms, such as He, C or Si. In other embodiments, ions of any type including dopants (from Group III or Group V), metals, impurities, neutral species, and halogens, may be used. The implant energy and dosage can vary, based on the species used and the desired depth of amorphization. In some embodiments, an implant energy of less than 10 keV is used, with a dose between 1e14 and 1e15. Such an implant may create an amorphized region having a thickness of about 20 nm or less. After the amorphization step, the silicide is applied to portions of the drain and source regions to form contacts. After the silicide is introduced, a fast anneal cycle, such as RTP, spike anneal, laser anneal or FLASH anneal, may be used. These anneal cycles are well known in the art.

In the present disclosure, the temperature of the substrate may be maintained at cold temperature by a cold temperature system which may include the platen. Detailed description of techniques and apparatus for maintaining the substrate at cold temperature may be found in U.S. patent application Ser. No. 11/770,220, Ser. No. 11/778,335, Ser. No. 11/733,445, 12/366,438, Ser. No. 11/696,506, Ser. No. 12/243,983, Ser. No. 12/244,013, and Ser. No. 12/132,939, each of which is incorporated in its entirety by reference.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of applying a silicide to a substrate comprising:
performing an implantation of ions into regions of said substrate at a cold temperature; and
introducing said silicide to at least a portion of said implanted regions.

2. The method of claim 1, wherein said implantation of ions comprises an implantation of ions used to dope said substrate.

3. The method of claim 2, wherein said ions are selected from atomic or molecular ions comprising elements from Group III or Group V.

4. The method of claim 2, further comprising performing an anneal cycle after said implantation of ions.

5. The method of claim 2, wherein regions comprises source regions or drain regions.

6. The method of claim 1, wherein said implantation of ions comprises a pre-silicide implant.

7. The method of claim 6, wherein said ions are selected from the group consisting of He, C and Si.

8. The method of claim 6, further comprising performing an implantation of dopants prior to said implantation of ions at cold temperature.

9. The method of claim 8, wherein said dopants are implanted at room temperature.

10. The method of claim 8, wherein said dopants are implanted at cold temperature.

11. The method of claim 8, wherein said dopants are selected from atomic or molecular ions comprising elements from Group III or Group V.

12. The method of claim 8, further comprising performing an anneal cycle between said implantation of dopants and said implantation of ions.

13. The method of claim 1, wherein said cold temperature is between 0 and −100° C.

14. A method of processing a CMOS device, comprising:
implanting dopants of a first species to create P type structures;
implanting dopants of a second species to create N type structures;
implanting ions into said N type structures and said P type structures at a cold temperature to amorphize said structures;
introducing silicide to said amorphized N type structures and P type structures.

15. The method of claim 14, wherein said first species comprises Group III elements.

16. The method of claim 14, wherein said second species comprises Group V elements.

17. The method of claim 14, wherein said ions are selected from the group consisting of He, C and Si.

18. The method of claim 14, wherein said cold temperature is between 0° C. and −100° C.
